(19) United States
(12) Patent Application Publication
(10) Pub. No.: US 2012/0178262 A1
(43) Pub. Date: Jul. 12, 2012

(54) Process for the manufacture of wafers for solar cells at ambient pressure

(75) Inventors: Marcello Riva, Hannover (DE); Elena Lopez Alonso, Dresden (DE); Dorit Linaschke, Dresden (DE); Ines Dani, Lichtenau (DE); Stefan Kaskel, Dresden (DE)

(73) Assignee: SOLVAY FLUOR GMBH, Hannover (DE)

(21) Appl. No.: 13/496,498

(22) PCT Filed: Sep. 15, 2010
(86) PCT No.: PCT/EP2010/063545

§ 371 Date: Mar. 16, 2012

(30) Foreign Application Priority Data
Sep. 18, 2009 (EP) 09170709.1

(51) Int. Cl. H01L 21/3065

(52) U.S. Cl. 438/714; 257/E21.218

(57) ABSTRACT

Solar cells are manufactured from P-type doped monocrystalline or polycrystalline silicon ingots by sawing wafers and applying an N-type doping. The wafers can be treated by etching them, in a plasma assisted process, with an etching gas containing or consisting of carbonyl fluoride. Hereby, the surface is roughened so that the degree of light reflection is reduced, or glass-like phosphorus-containing oxide coatings caused by phosphorus doping are removed. Carbonyl fluoride is also very suitable to selectively etch silicon oxide in silicon oxide/silicon composites.

The present invention which claims benefit of EP patent application number 09170709.1 filed on Sep. 18, 2009 the complete content of which is incorporated herein by reference, relates to a process for the manufacture of wafers for solar cells.

Solar cells are applied to convert solar light into electric current. They are usually manufactured from monocrystalline blocks of boron-doped silicon (P-type doping) or from cast silicon ingots (polycrystalline silicon, P-type doped with boron) by sawing wafers in desired size out of the bulk material. Then, a layer of silicon doped with phosphorous is formed to provide an N-type doped coating. For example, the wafer can be contacted with POCl₃. Contact electrodes are then applied, e.g. by evaporating metal onto the surface of the cell. Several respective solar cells are then arranged to form a solar panel. If desired, the cell may also contain other dopants, e.g. copper, as described by U.S. Pat. No. 4,249,957.

Cells manufactured in this manner still may have some drawbacks. For example, the surface of the cells ought to be non-reflective because light is better absorbed by them in this case. The wafers may have cracks from the sawing process. During phosphorous doping, a phosphorus-containing glass-like layer may form which is undesired. This is described by J. Rentsch, D. Decker, M. Hofmann, H. Schlemm, K. Roth and R. Preu, in a paper titled “Industrial realization of dry plasma etching for PSG removal and rear side emitter etching”, presented at the 22^{nd} European Photovoltaic Solar Energy Conference and Exhibition, 3-7 September in Milan, Italy. In this paper, it is described that wet etching phosphorus silicate glass (called “PSG” in the paper) is characterized by high water and chemical waste disposal as well as high mechanical impact. It is further mentioned that PFCs (perfluorocarbons) and SF₆ are commonly used for saw damage removal as well as oxide etching during solar cell processing. In experiments, PSG were etched using CF₄ (a perfluorocarbon) and hydrogen were used. Other plasma treatments of the wafer are performed using SF₆. PFCs and SF₆ are considered to have a certain GWP.

According to international patent application WO 2009/092453 the content of which is incorporated entirely herein by reference, solar cells are manufactured from a silicon wafer comprising a step of etching the wafer with an etching gas comprising carbonyl fluoride, fluorine, or nitrogen trifluoride or mixtures thereof.

It was now found that wafers for solar cells can be manufactured comprising a step of etching a wafer with an etching gas comprising carbonyl fluoride, in a plasma at atmospheric pressure or higher. The actual atmospheric pressure corresponds to the atmospheric pressure surrounding the plasma apparatus. The atmospheric pressure may vary, of course, depending on the altitude and the actual weather conditions. A calculation can be made using the calculation tool “Standard Atmosphere Calculator” on http://www.aviation.ch/tools-atmosphere.asp which refers to “The ICAO Standard Atmosphere is a hypothetical model of vertical distribution of atmospheric temperature, pressure, and density that, by international agreement, is taken to be representative of the atmosphere for purposes of pressure altimeter calibrations, aircraft performance calculations and aircraft design”. For example, at sea level, the calculated standard value is 1013 hPa. At an altitude of 500 m, the pressure is calculated to be 954 hPa. Preferably, the process of the invention is performed at a pressure which ranges from atmospheric pressure—the atmospheric pressure is included in the range—and equal to or lower than 1.5 bar (abs.).

Most preferably, the method of the invention is performed at atmospheric pressure.

The term “atmospheric pressure” in the context of the present invention preferably denotes a pressure range of the ambient pressure ±300 Pa. If an etching tool is located at about sea level, the ambient pressure can be expected to be between about 970 hPa and 1040 hPa, depending on the weather conditions (unless the pressure in the facility is artificially kept at a specific level). Thus, at sea level, the etching is preferably performed at a pressure which ranges from about 967 hPa to about 1043 hPa. If the facility is located at an altitude of 500 m, the ambient pressure (unless the pressure is kept in the facility at an artificial level) can be expected to be between about 915 hPa to about 985 hPa, and the process of the invention is preferably performed at a pressure in a range between about 912 hPa to about 988 hPa. If the ambient pressure in the facility is artificially kept at, for example, 1015 hPa, then, in this case, the process is preferably performed at a pressure in a range between about 1012 hPa and 1018 hPa.

In one preferred embodiment, the pressure lies in a range from ambient pressure to ambient pressure +300 Pa; ambient pressure and ambient pressure +300 Pa are included in the range. Thus, to give an example, if the facility is located at sea level, the etching is preferably performed at a pressure which ranges from about 970 hPa to about 1043 hPa.

Static etching and dynamic etching are possible.

Carbonyl fluoride has no impact on the ozone layer and no GWP. Carbonyl fluoride can be prepared, for example, by photochemical oxidation of CHF₃, by reaction of CO with elemental fluorine or by chlorine-fluorine exchange of COCl₂ with fluorinating agents.

It is preferred that neither SF₆, NF₃, hydrofluorocarbons, perfluorocarbons, perfluoroethers or other etchants are comprised which have a negative effect on the ozone layer, or which have a GWP₁₀₀ of more than 15. It is especially preferred that no additional etchant is contained.

The process can be applied for several purposes. For example, it can be applied to etch silicon. It can also be applied to remove phosphorous-silica glass (PSG) from wafers. It also can be applied to etch silicon oxide selectively over silicon. These alternatives will now be explained in detail.

The process of the invention is preferably used to etch silicon wafers, more preferably, monocrystalline or polycrystalline silicon wafers in the manufacture of solar cells. The silicon wafer is preferably cut (e.g. by sawing) from a P-type doped (especially boron doped) polycrystalline or monocrystalline silicon block. Carbonyl fluoride can be used for the repair of saw damage and texturization (the surface of the wafer is preferably a silicon surface which is etched for roughening of the surface to reduce light reflection), for the removal of front and rear side short, for the manufacture of antireflective coatings of silicon nitride, and especially for the removal of phosphorous glass and for etching silicon oxide layers on silicon.

The etch process of the present invention can also be used to etch the parasitic emitter on the rear of the solar cell.

According to one embodiment, the surface of the wafer used for the solar cell is modified (it is assumed that it is roughened) by the etching process of the present invention. Roughening of the wafer surface by etching reduces the reflectivity and thus enhances the efficiency of the solar cell. Reflectivity is considered reduced if the total hemispherical reflectivity (averaged over all wavelengths) expressed by the intensity of incident light divided by reflected light is smaller for the surface-treated silicon wafer in relation to the untreated silicon wafer.

The etching treatment is performed for a time which is sufficient to provide the desired reduction of reflectivity. Preferably, the treatment is performed for equal to or more than 1 second. Preferably, the treatment is performed for equal to or less than 10 minutes, preferably for equal to or less than 5 minutes. Etching is preferably performed until about equal to or more than 0.1 μm of the surface are etched away. Preferably, it is performed until equal to or less than 500 μm, preferably, until equal to or less than 100 μm are etched away from the surface, especially until equal to or less than 20 μm are etched away. Often, a few μm are etched away, for example equal to or less than 10 or even equal to or less than 5 μm.

It is possible to induce the plasma using an ultra-short pulsed laser.

It was found that the etching process, especially of silicon, is very effective when the temperature of the substrate is equal to or higher than 100° C. The substrate temperature is preferably equal to or lower than 400° C., preferably equal to or lower than 375° C. The substrate temperature is very preferably between 150° C. and 350° C.

The etching can also be applied to the rear side of the solar cell to improve adhesion of the electrodes which are applied, as is described below.

In a preferred embodiment, wafers which have a glasslike phosphorus-silica glass coating (PSG) are treated with carbonyl fluoride according to the process of the invention at atmospheric pressure or even higher. Such coatings may be the undesired result during the step of doping the silicon wafer with phosphorus compounds to achieve the N-type doping. This glasslike coating reduces the electric contact of the electrode which is applied on the surface of the cell. It was found that this glass-like coating can be removed by treating it in a plasma with carbonyl fluoride, preferably together with oxygen, nitrogen, helium and/or argon.

At atmospheric pressure and above, the selectivity of carbonyl fluoride in view of PSG and silicon was found to be over 15:1, this means PSG is preferably etched—as is, of course, desirable. The selectivity of NF₃ was determined to be only slightly above 1,6:1, thus much lower. The selectivity of a mixture of CHF₃ and oxygen was 12:1. Under comparable conditions, the dynamic PSG etch rate of carbonyl fluoride in μm·m/min was 1.23, compared to 0.052 for the mixture of CHF₃ and oxygen and of 2.43 for NF₃. Consequently, it has a higher selectivity than the mixture of CHF₃ and oxygen and a much higher etch rate, and compared to NF₃, the etch rate is lower, but the selectivity is clearly superior.

In another preferred embodiment, silicon oxide layers on silicon are etched. It was found that carbonyl fluoride is very selective towards etching silicon oxide, this means, it etches silicon oxide faster than silicon at atmospheric pressure or above.

During plasma-induced etching treatment, the wafer heats up. So, if needed, either the wafer must be cooled if a threat of overheating it exists, or the treatment must be interrupted from time to time so that the wafer cools.

The gases leaving the plasma reactor comprise unreacted etchant, CO, SiF₄, phosphorous fluorides and other reaction products. HF is detected only in minimal amounts. They can be washed with water, especially alkaline water, to remove any HF, carbonyl fluoride, SiF₄ or fluorine. Any oxygen, nitrogen, helium or argon passing the washer can be recovered or passed to the environment. The simple removal of the marginal amounts of formed HF and carbonyl fluoride in alkaline water or by other well-known methods compared with other etching gases is a further advantage.

The wafers treated according to the process of the present invention can then be used to produce a solar cell. Especially, contact electrodes are attached to the wafer. These contact electrodes are needed to withdraw electric current (usually direct current) from the cell. A preferred way to apply contact electrodes is evaporating metal onto the wafer as mentioned in U.S. Pat. No. 4,249,957. A contact electrode from titanium-palladium-silver is very suitable. There are alternative methods which can be used to apply contact electrodes. For example, a paste can be applied which contains conductive particles, e.g. silver particles, to form a pattern on the wafer, the wafer is fired, and a conductive pattern is formed on the wafer which functions as electrode. This alternative is described in EP-A-0 542148.

A process for the manufacture of solar cells using wafers treated according to the process of the present invention is also an embodiment of the present invention.

The solar cells obtained by the process of the present invention have a very low degree of reflexivity, and/or they contain cracks in keyhole-like form.

The treatment of the present invention is preferably performed by a plasma-assisted treatment in a plasma reactor. The plasma can be induced directly or remote. Such plasma reactors are generally known, for example, from German patent application DE 10239875 and German patents DE 102004015216 B and 102004015217 B.

In the following, preferred gases and gas mixtures applicable in the process of the present invention are described in detail.

Carbonyl fluoride can be applied as neat substance or in admixture with other gases, for example, together with at least one gas selected from the group consisting of oxygen, nitrogen, N₂O, helium and argon. If it is applied together with an additional gas, it is preferably applied together with oxygen and/or inert gases, for example, it can be applied together with nitrogen, helium and/or argon. It is preferably applied together with argon and nitrogen. Argon and nitrogen stabilize the plasma while carbonyl fluoride serves as etch gas. The mixtures can be prepared before introducing them into the reactor, or they can be introduced separately. It is also possible to mix only two or more constituents before introducing them into the reactor, and to introduce another constituent separately into the reactor. For example, carbonyl fluoride can be introduced into the reactor separately from from a pre-mixed mixture of nitrogen and argon.

Especially in apparatus with high power plasma, it is often possible to use neat carbonyl fluoride. In plasma apparatus with lower plasma power, it may be advisable to apply mixtures of carbonyl fluoride and argon (optionally together with nitrogen) because argon has a positive effect, e.g. in stabilizing the plasma. Carbonyl fluoride diluted with nitrogen, helium and/or argon also may allow safer handling. It was found that carbonyl fluoride is a very efficient etching gas even if it is applied together with argon and nitrogen. Good results are achieved even with a very low concentration of carbonyl fluoride in the plasma reactor. For example, a concentration of 0.5 to 5% by volume of carbonyl fluoride, the remainder being argon and nitrogen, gives good results. The carbonyl fluoride content may also be higher. It can be equal to or lower than 50% by volume.

Mixtures consisting of carbonyl fluoride (preferably with carbonyl fluoride content as given above), nitrogen and argon are especially suitable. Preferably, argon is the predominant component. Often, its content in the gas mixture in the reactor is between 40 and 80% by volume. The content of nitrogen is preferably between 10 and 30% by volume. The remainder to 100% by volume is carbonyl fluoride.

The advantage of the present invention is that aqueous etching is substituted by a fast, clean method. In-line solar wafer etching is possible with high throughput. The breaking rate of thin solar wafers is decreased by reduced handling and soft processing. Carbonyl fluoride has a low GWP, and can be removed easily from any vents leaving the reactor. The process is technically advantageous because due to the comparably high pressure it is less probable that gas (air, moisture) from the atmosphere surrounding the plasma treatment apparatus enters the interior of the apparatus. Carbonyl fluoride has a high selectivity towards etching of PSG and silicon oxides.

Especially in apparatus with high power plasma, it is often possible to use neat carbonyl fluoride. In plasma apparatus with lower plasma power, it may be advisable to apply mixtures of carbonyl fluoride and argon (optionally together with nitrogen) because argon has a positive effect, e.g. in stabilizing the plasma. Carbonyl fluoride diluted with oxygen, nitrogen, helium and/or argon also may allow safer handling.

Should the disclosure of any patents, patent applications, and publications which are incorporated herein by reference conflict with the description of the present application to the extent that it may render a term unclear, the present description shall take precedence.

The following examples are intended to explain the invention further without intending to limit it.

### EXAMPLES

Etching equipment: An etch reactor with linear extended DC (direct current) arc plasma source and double waste gas extraction system was used. The working width was 250 mm. As plasma gas, a mixture of argon and nitrogen was used.

### Example 1

### Etching of Silicon

A silicon item was introduced into the plasma reactor. The flow of argon was regulated to 60 slm (standard liter per minute), the flow of nitrogen was regulated to 20 slm. The flow of carbonyl fluoride was varied. The temperature of the silicon item was kept at about 350° C. The etch rate at a given flow of carbonyl fluoride is given in table 1.

TABLE 1
Etch rate of silicon depending on the gas flow of COF₂

| COF2 flow [slm] | Dynamic etch rate [μm · m/min] |
|---|---|
| 0.5 | 0.25 |
| 1 | 0.35 |
| 1.5 | 0.4 |
| 2 | 0.5 |
| 2.5 | 0.55 |
| 3 | 0.6 |
| 3.5 | 0.65 |

The results in table 1 demonstrate that the dynamic etch rate can be triplicate or almost triplicate by raising the concentration of carbonyl fluoride.

### Example 2

### Silicon Etching at Varying Temperatures

Example 1 was repeated, but the carbonyl fluoride gas flow was set to 0.5 slm while the temperature of the substrate was varied. The results are given in table 2.

TABLE 2
Etch rate of silicon depending on the substrate temperature

| Substrate temperature [° C.] | Static etch rate [μm/min] |
|---|---|
| 190 | 1.1 |
| 230 | 1.16 |
| 265 | 1.2 |
| 310 | 1.33 |
| 350 | 1.41 |
| 400 | 1.415 |

The results in table 2 demonstrate that the etch rate increases rapidly when the substrate temperature is in a range of about 250° C. to 350° C.

### Example 3

### Etching of Phosphorous-Silicate Glass (PSG) with Carbonyl Fluoride

A PSG layer on a wafer was etched using carbonyl fluoride. The selectivity of carbonyl fluoride towards PSG and silicon was found to be 15.3:1. The dynamic PSG etch rate was determined to be 1.23 μm·m/min.

### Comparison Example

### Etching of PSG using NF₃

NF₃ was applied under the same conditions. The etch rate was determined to be 2.43 μm·m/min, but the selectivity towards PSG was only 1.6:1.

Example 3 and the comparison example demonstrate the outstanding selectivity of carbonyl fluoride for PSG removal.

1. A method for manufacturing a wafer for a solar cell comprising a step of plasma-assisted etching of the wafer with an etching gas comprising carbonyl fluoride at a pressure which is equal to or greater than atmospheric pressure.

2. The method of claim 1 wherein a silicon wafer for a solar cell is manufactured.

3. The method of claim 1 wherein the method is performed at atmospheric pressure.

4. The method according to claim 3 wherein the atmospheric pressure ranges between ambient pressure −300 Pa and ambient pressure +300 Pa.

5. The method according to claim 1 wherein a wafer having a phosphorus-silicon-glass coating is etched to remove the phosphorus-silicon-glass coating.

6. The method of claim 1 wherein silicon is etched.

7. The method according to claim 6 wherein the surface of the wafer is a silicon surface which is etched to roughen the surface.

8. The method according to claim 1 wherein silicon oxide or a silicon oxide/silicon composite on the surface of the wafer is treated via said plasma-assisted etching to selectively remove the silicon oxide.

9. The method according to claim 1 wherein carbonyl fluoride is applied together with at least one gas selected from the group consisting of oxygen, nitrogen, N₂O, helium, and argon.

10. The method according to claim 9 wherein carbonyl fluoride is applied together with argon, nitrogen, or argon and nitrogen.

11. The method of claim 10 wherein carbonyl fluoride, argon and nitrogen are introduced separately into an etching chamber.

12. The method of claim 10 wherein carbonyl fluoride and a mixture of argon and nitrogen are introduced separately into an etching chamber.

13. The method according to claim 1 wherein the wafer has a temperature ranging from 150° C. to 350° C.

14. The method according to claim 10 wherein etching is performed with a gas mixture consisting of carbonyl fluoride, argon, and nitrogen.

15. A method for manufacturing a solar cell wherein a wafer produced by the method according to claim 1 is used in said solar cell.

16. The method according to claim 6 wherein the wafer has a temperature ranging from 150° C. to 350° C.
